(19) United States
(12) Patent Application Publication
(10) Pub. No.: US 2008/0174969 A1
(43) Pub. Date: Jul. 24, 2008

(54) Printed Board Assembly With Improved Heat Dissipation

(75) Inventor: Johan Sandwall, Floda (SE)

Correspondence Address: ERICSSON INC., 6300 LEGACY DRIVE, M/S EVR 1-C-11, PLANO, TX, 75024, US

(73) Assignee: TELEFONAKTIEBOLAGET LM ERICSSON (PUBL), Stockholm (SE)

(21) Appl. No.: 11/720,449

(22) PCT Filed: Nov. 30, 2004
(86) PCT No.: PCT/SE04/01762

§ 371 Date: May 30, 2007

(51) Int. Cl. H05K 7/20; H05K 3/00

(52) U.S. Cl. 361/720; 29/829

(57) ABSTRACT

A multi-layer printed board assembly (PBA) with improved heat dissipation characteristics. An electronic component is surface mounted on a main surface at least partially over a cooling component arranged integrally in the PBA. The cooling component transports heat from the electronic component through the PBA in a first direction (x) essentially perpendicular to the main surface of the PBA, and in a second direction (y) essentially parallel to the main surface of the PBA.

### TECHNICAL FIELD

The present invention discloses a printed board assembly, a PBA, which has a first supporting layer of a non-conducting material and which also comprises a first layer of a conducting material and a first electronics component, as well as a first cooling component for transporting heat from the first electronics component.

### BACKGROUND ART

Many electronics components that are used in contemporary printed board assemblies, PBA:s, generate a great deal of heat. This is especially true of, for example, such components as high power amplifiers (HPA:s) and power transistors.

To cool the PBA:s then becomes a problem, to which many solutions have been presented. Solutions which are known at present often include production steps which necessitate manual labour or use via holes.

Some problems with these known solutions are that via holes can only dissipate a limited amount of heat, and manual labour will cause the product to become rather expensive.

### DISCLOSURE OF THE INVENTION

There is thus a need for a PBA which can dissipate heat from, for example, an HPA in a manner which is more efficient than solutions known today. Ideally, it should be possible to produce such a PBA without any manual labour.

These needs are addressed by the present invention in that it discloses a printed board assembly, a PBA, which comprises a first supporting layer of a non-conducting material, also comprising a first layer of a conducting material and a first electronics component as well as a first cooling component for transporting heat from the first electronics component.

According to the invention, the first electronics component is surface mounted on the PBA so that it at least partially covers the first cooling component, and the first cooling component is arranged integrally in the PBA.

Additionally, the first cooling component is arranged in the PBA so that it can transport heat generated by the first electronics component in a first direction which direction is essentially perpendicular to a first main surface of the PBA, as well as in a second main direction which is essentially parallel to said first main surface of the PBA.

Suitably, the first electronics component is surface mounted on the PBA by means of soldering, gluing or pressure applied from an external component.

Thus, by means of the invention, and as will become evident from the following detailed description, a PBA is obtained which has a cooling structure with a higher degree of performance than known such structures. The PBA of the invention is also easier to manufacture by automated means than known PBA:s.

The invention also discloses a method for manufacturing the PBA described above.

### BRIEF DESCRIPTION OF THE DRAWINGS

The invention will be described in more detail in the following, with reference to the appended drawings, in which

FIG. 1 shows a cross-sectional view from the side of a basic PBA according to the invention, and

FIG. 2 shows a cooling structure for use in a PBA of the invention, and

FIG. 3 shows a cross-sectional view from the side of a PBA according to the invention, and

FIG. 4 shows a flowchart of some of the major steps in a production method according to the invention.

### EMBODIMENTS

Initially, it should be pointed out that in this text, the term “Printed Board Assembly” will be used throughout to describe the invention. Generally, the term Printed Circuit Board, PCB, is used to denote a circuit board without any components mounted on it, while the term Printed Board Assembly, PBA, is generally used to described the combination of a PCB and one or several components which are arranged on the PCB. In order not to obscure the description, the term PBA is however used consistently in this text.

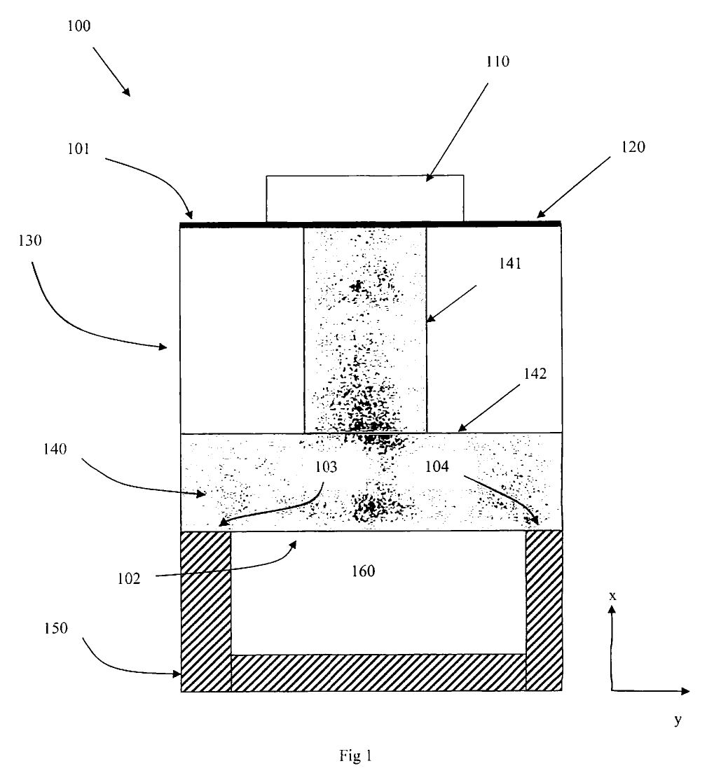

FIG. 1 shows a cross-sectional view from the side of a PBA 100 according to the invention. The PBA 100 is a very “basic” version of the invention, and serves mainly to illustrate a principle behind the invention.

As can be seen in FIG. 1, the PBA has a first upper main surface 101, and comprises a first supporting layer 130 of a non-conducting laminate material such as, for example, FR4. On top of the laminate layer 130, there is arranged a layer 120 of a conducting material such as copper, said layer suitably being arranged as a desired circuit pattern. In this case, it is thus the layer 120 of a conducting material which mainly forms the first main surface 101 of the PBA.

As also shown in FIG. 1, the PBA 100 also comprises a first electronics component 110, which is surface mounted on the PBA by means of soldering and connected to points on the circuit pattern 120, also by means of soldering. As alternatives, which will be elaborated on later in this text, the first electronics component may be fixed in place by means of gluing or by an external component arranged on the PBA or external to the PBA, i.e. in a rack or similar arrangement, which applies pressure on the first electronics component in the direction of the first main surface 101 of the PBA.

In order to achieve efficient dissipation of the heat generated by the electronics component 110, the PBA 100 also comprises a first cooling component 140. The cooling component is made of a material which is highly heat-conducting, such as, for example, copper or brass or some other such metal or metal alloy.

A principle behind the invention is that heat generated by the electronics component should be dissipated efficiently in a first direction into the PBA, a direction which is essentially perpendicular to the first main surface 101 of the PBA, as well as in a second direction which is essentially parallel to said first main surface 101. The first direction is the “x”-direction shown in the coordinate system in FIG. 1, and the second direction is the “y”-direction in the same coordinate system.

In order to achieve the desired heat dissipation, the first cooling component comprises a first 141 and a second 142 main part, which together give the component the shape of an “inverted capital T”. It should be noted that this shape is merely an example of an embodiment, the cooling component can be given a rather large variety of shapes in order to achieve the desired results, as will become clear from the following description.

Regarding the cross-sectional shape or shapes of the two parts of the cooling component 140, these can be varied in a large number of ways within the invention, but the larger part 142 should suitably have a cross-sectional shape which coincides, or does not interfere with, the general outer shape of the PBA 100, i.e. in this case rectangular.

In the embodiment 100 shown in FIG. 1, the parts of the cooling component 140 have different cross-sectional areas, the first part 141 having a smaller such area A₁ than the area A₂ of the second part 142. Also, the cooling component is arranged integrally in the PBA so that the “base of the T”, i.e. that end of the smaller part 141 which is not in contact with the larger part 142, is closely adjacent to, or in contact with the first main surface 101 of the PBA. This is in order to facilitate the transfer of heat from the electronics component to the cooling component.

FIG. 1 also shows one of the reasons for the “inverted T-shape” of the cooling component 141: heat which via the first part 141 of the cooling component is transported in the x-direction, i.e. into the PBA from the first main surface 101 will, by means of the second part 142 of the cooling component, i.e. the “cross-bar” of the T, be transported sideways, i.e. in a direction which is essentially parallel to the first main surface 101 of the PBA, the “y”-direction in the coordinate system in FIG. 1.

FIG. 1 shows one of the reasons for the desire to transport heat sideways: the PBA is intended to be arranged in a rack or a similar structure in such a way that the surface of the PBA which is opposite the first main surface 101 (i.e. a lower main surface of the PBA) is in mechanical contact with a part 150 in the rack which can conduct heat.

It is to be noted that the part 150 is not in contact with the entire bottom surface of the PBA, instead it only contacts an outer sub-area of the bottom area of the PBA. Said sub-area can be a circumferential area, or, as indicated in FIG. 1, a first 103 and a second 104 “strip” along opposing edges of the bottom surface of the PBA.

Due to the fact that the external cooling surface only contacts the circumference of the PBA, a space or cavity 160 is left into which components from the PBA can protrude, thus creating the possibility of a “two-sided” PBA with highly efficient cooling.

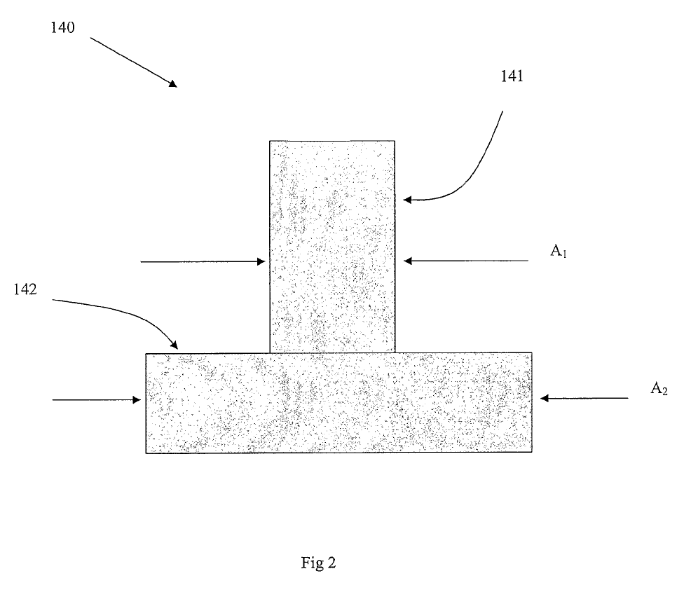

FIG. 2 shows the first cooling component 140. From this drawing, the shape of the component 140 can be seen clearly, i.e. there is a first part or section 141 which will contact or be in close proximity to the first main surface 101, and a second part or section 142 which, by virtue of its main direction of extension when arranged in the PBA, can transfer heat from the first part 141 in a direction which deviates from a main direction of extension of the first part 141. Suitably, the second part 142 is at an angle smaller or greater than zero degrees relative to the first part 141, 341, of the cooling component.

Said main directions of extension when the cooling component is arranged in the PBA are, for the first part 141 the “x”-direction of FIG. 1, and for the second part 142 the “y”-direction shown in FIG. 1.

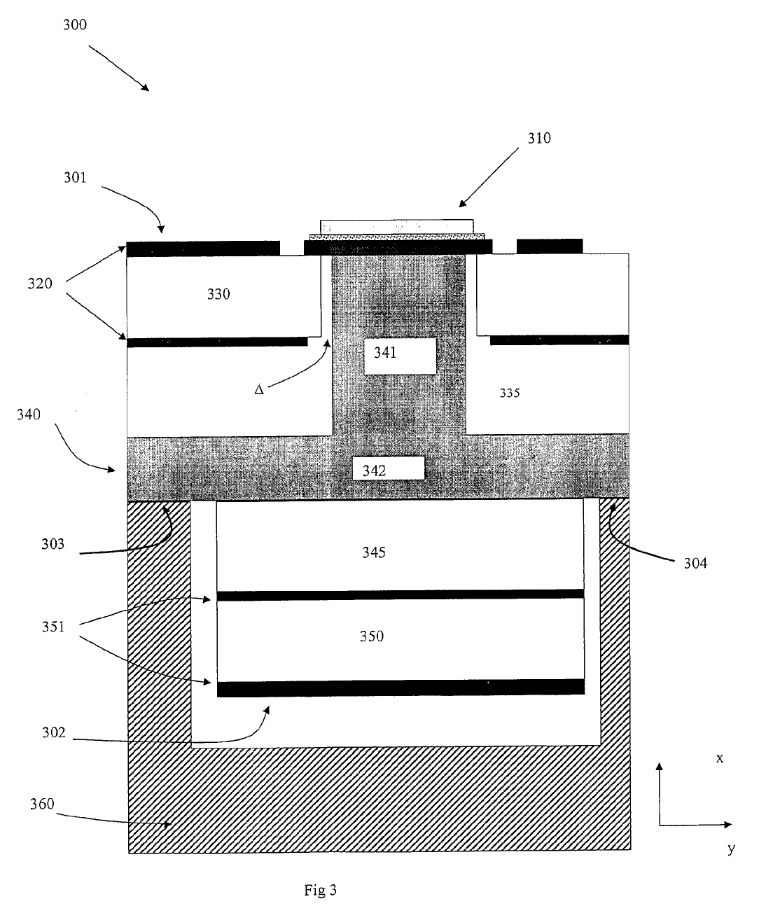

FIG. 3 shows a more detailed PBA 300 according to the invention. As can be seen, this PBA 300 comprises a plurality of alternating layers of supporting non-conducting laminate 330 and 345, and layers of so called “prepreg” 335, 345.

The material which will be referred to consistently in this text as “prepreg” is used to fix rigid laminates together and to fill spacing between, for example, layers inside Printed Circuit Boards so that air pockets are essentially eliminated. Prepreg has a semi-cured chemistry, and can therefore be formed under special pre-defined combinations of heat, pressure and vacuum.

Once the prepreg chemistry has cured completely, it is fixed and will stay in that shape.

As an alternative to prepreg, so called bonding films can also used to fix different material layers to each other, and to fill spaces or cavities between material layers inside Printed Assembly Boards. Bonding films are also formed by heat, pressure and vacuum, but can be melted several times. Returning now to the PBA 300, it also has circuit patterns 320, 351, made from a layer of a conducting material such as copper on one or both sides of the layers of non-conducting laminate.

Also, the PBA 300 comprises a first cooling component 340 shaped and arranged as the corresponding component shown in FIGS. 1 and 2, and a first electronics component 310 which is surface mounted on the PBA 300 by one of the means mentioned in connection with the description of the PBA in FIG. 1.

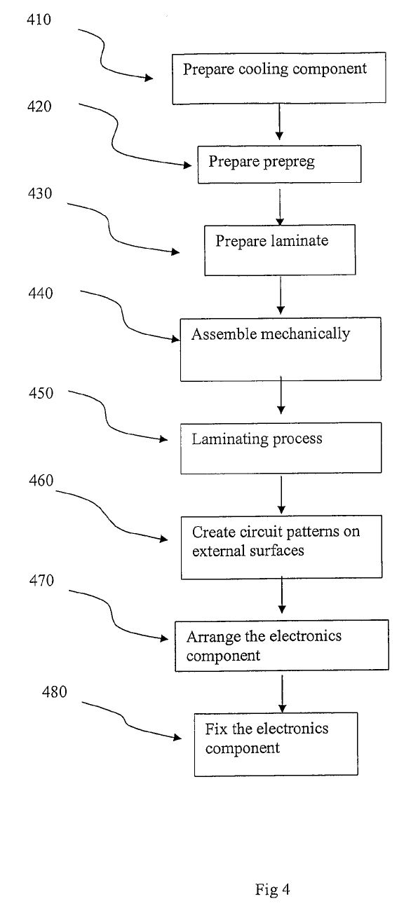

With the aid of FIG. 4, which is a flowchart outlining some of the major steps in the production of the PBA 300, the PBA 300 will now be described in closer detail. It should be pointed out that the steps shown in FIG. 4 and described below need not be carried out in the order shown and described, the important thing is the end result, i.e. the finished PBA 300.

As an initial step, block 410 in FIG. 4, the first cooling component 340 is prepared, i.e. given the shape shown and described above, and with the desired dimensions. The component should be made from a material which has a high capacity for conducting heat, for example copper, brass or other such metals or metal alloys. The shaping of the component 340 can be carried out in a variety of ways which are known to those skilled in the field, for example by means of milling.

The next step is shown as block 420 in FIG. 4: a layer of so called “prepreg” is prepared. The preparations of the prepreg include giving the layer the desired dimensions, i.e. the width and length of the future PBA, as well as making a hole or a window in the layer of prepreg, said hole having a dimension corresponding to the cross sectional area A₂ of the narrower part 141 of the cooling component 340. Suitably, the hole in the layer of prepreg is created by means of milling, although other processes are possible, for example drilling. The layer of prepreg thus prepared will become the layer shown as 335 in FIG. 3.

Next, block 430 in FIG. 4, a layer of a non-conducting laminate such as, for example, FR4, is prepared. The preparations in this case include making a hole or a “window” in the layer, said window in this case being slightly larger than A₁, i.e. the smaller of the cross-sectional areas of the cooling component. The difference in size between the hole in the laminate and A₁ can suitably be in the area of 1-5% and is shown as “Δ” in FIG. 3. The laminate layer prepared in this step will become the layer shown as 330 in FIG. 3.

Next, an optional step which is not shown in FIG. 4 can be carried out: if it is desired to have circuit patterns on that side of the laminate layer which will face “inwards” in the PBA 300, these patterns will now be arranged on the laminate. This is done by conventional means, such as for example etching or using photoresist, etc, and will thus not be described in further detail here. In FIG. 3, the laminate layer 330 is shown as having circuit patterns on both of its main surfaces.

The PBA 300 in FIG. 3 is shown as having a number of layers of non-conducting laminate, 330, 350, as well as a number of layers of prepreg, 335, 345, where the layers of laminate are provided with circuit patterns on one or both of their sides. It will be appreciated by those skilled in the field that the PBA 300 can be provided with a more or less arbitrary number of layers arranged as in FIG. 3. For this reason, the preparation of all of the layers shown in FIG. 3 will not be described in detail here.

Accordingly, the laminate layer 350 will be prepared in the manner described above, as will the prepreg layer 345. Naturally, those layers which are to be arranged on the “boftom” of the cooling component 340, i.e. flush against the bottom surface of the part 342 will not need to have a hole or a window made in them.

Thus, a number of layers of prepreg and laminate will now have been prepared by giving them the desired mechanical dimensions, including the opening for the cooling component 340. As indicated in block 440 in FIG. 3, these layers are now assembled mechanically in the desired order.

With the layers of the future PBA are arranged in the desired order, the next step is to apply a so called “vacuum laminating process”, box 450 in FIG. 4, to the future PBA in order to fix the layers to each other permanently. This can, for example, be done in a so called “vacuum lamination oven”, in which the temperature will vary depending on the materials involved, i.e. the prepreg and the laminate.

During the lamination process, the prepreg will become liquid, which explains the reason for making the opening in the laminate layers slightly larger (“Δ”) than the width of the cooling component: during the laminating process, the future PBA, i.e. the layers which have been arranged mechanically in the proper order, is subjected to pressure from directions which correspond to the upper and lower sides of the PBA, i.e. the upper and lower main surfaces 101 and 102 of FIG. 1 and 301, 302, of FIG. 3.

Due to this pressure, the liquefied prepreg will be pressed into the openings Δ between the laminate layers and the cooling component, so that essentially all play is eliminated.

Following the laminating process, the PBA is removed from the vacuum oven and the prepreg is allowed to harden. If necessary, some surface processing can then be carried out in order to create smooth main surfaces of the PBA 300.

The next step, as shown in box 460 in FIG. 4, is to create circuit patterns on the upper and/or lower main surface 301, 302, of the PBA 300. The upper surface at this stage preferably consists of a non-conducting laminate 330, 350, covered with a thin layer of copper or some other conducting material, in which circuit patterns are created by well known conventional means, for example photolithographic methods.

As a final major step, boxes 470 and 480 in FIG. 4, the high power electronics component 310 for which the cooling component 340 is intended is arranged on the PBA, and fixed by means of soldering to the mentioned layer 320 of a conducting material.

As shown in FIG. 3, there will now be a cooling component 340 arranged directly beneath at least part of the high power component 310, and the cooling component will be able to conduct heat generated by the high power component in a first direction of the PBA, in this case in the direction shown as “x” in the coordinate system in FIGS. 1-3, i.e. in a direction from the first main surface 101, 301, towards the second main surface 102, 302.

Additionally, the cooling component 340, 140, due to its part 342, 142, is also able to transport heat in a second direction, the “y”-direction of FIGS. 1-3. Thus, heat generated at the surface of the PBA by the electronics component 310 will be transported first in the x-direction and then in the y-direction.

One purpose of transporting heat in this way (first x, then y) emerges from FIG. 3: as shown in FIG. 3, the PBA is arranged in, for example a rack, where parts 303, 304, of the lower main surface 302 of the PBA come into contact with a mechanical part 360 of the rack which can act as an external heat sink.

It is to be noted that the external part 360 is not in contact with the entire bottom surface of the PBA, instead it only contacts an outer sub-area of the bottom area of the PBA. Said sub-area can be a circumferential area, or, as indicated in FIG. 1, first 303 and second 304 “strips” along opposing edges of the bottom surface of the PBA.

Due to the fact that the external cooling surface only contacts the circumference of the PBA, a space 160 is left into which components from the PBA can protrude, thus creating the possibility of a “two-sided” PBA with highly efficient cooling. In FIG. 3, two layers 345, 350, of the PBA are shown arranged on the “bottom” side 302 of the PBA, said layers extending in the x-direction in such a way that room is left for the strips which will contact the external surface 360. The strips are, in this case, parts of the cooling component 340.

The invention is not limited to the examples of embodiments shown above, but can be varied freely within the scope of the appended claims. For example, the shape of the cooling component 140, 340, may be varied in a large number of ways while maintaining the ability of transporting heat. Also, the directions shown above in which heat is transported, i.e. the x- and y-directions, need not be directions which are perpendicular (x) and parallel (y) to the main surfaces of the PBA, these directions can be altered by altering the way in which the cooling component is arranged in the PBA, and by altering the shape of the cooling component.

As an obvious alternative to the embodiment shown in FIG. 3, the PBA can be arranged so that the mechanical part 360 of the rack which can act as an external heat sink instead comes into contact with the PBA from the first main surface 301 of the PBA 300. In such an embodiment, with renewed reference to FIG. 3, one or more outer edges of the first main surface 301 of the PBA might be removed to expose the larger part 342 of the cooling component 340.

When the PBA 300 then is arranged in a rack or a similar structure, the part 360 will envelop the upper surface of the PBA, in the same manner as it envelops the lower main surface of the PBA in FIG. 3.

1-8. (canceled)

9. A printed board assembly (PBA), comprising:
a first supporting layer of a non-conducting material;
a first layer of a conducting material;
a first electronics component surface mounted on the PBA; and
a first cooling component arranged integrally in the PBA for transporting heat from the first electronics component;
wherein:
the first electronics component is mounted at least partially over the first cooling component; and
the first cooling component is arranged in the PBA so that it transports heat generated by the first electronics component in a first direction (x) which is essentially perpendicular to a first main surface of the PBA and in a second main direction (y) which is essentially parallel to the first main surface of the PBA.

10. The PBA as recited in claim 9, wherein the first electronics component is surface mounted on the PBA by means of soldering, gluing, or pressure from an external component.

11. The PBA as recited in claim 9, wherein the cooling component includes a first part and a second part, the second part being arranged at an angle other than zero degrees relative to the first part of the cooling component.

12. The PBA as recited in claim 9, wherein the cooling component is shaped as a capital “T” due to the arrangement of the first part and the second part of the cooling component, the first part of the cooling component being arranged in a hole in the PBA.

13. A method of manufacturing a printed board assembly (PBA), comprising the steps of:
preparing an opening in a first layer of a non-conducting laminate for receiving a first cooling component;
preparing the first cooling component for being fitted into the opening in the laminate;
fitting the cooling component into the laminate;
preparing circuit patterns on at least a first main side of the laminate;
processing the first laminate layer and the first cooling component so that they together become a PBA;
preparing and fitting the first cooling component into the laminate in such a way that it can transport heat in a first direction (x) which is essentially perpendicular to a first main surface of the PBA and in a second main direction (y) which is essentially parallel to said first main surface of the PBA; and
surface mounting a first electronics component on the first main surface of the PBA, at least partially over the first cooling component.

14. The method as recited in claim 13, wherein the first electronics component is surface mounted to the PBA by means of soldering, gluing, or applying pressure from an external component.

15. The method as recited in claim 13, wherein the cooling component is prepared for being fitted into the laminate by giving it a first and a second part, the second part being arranged at an angle other than zero degrees relative to the first part of the cooling component.

16. The method as recited in claim 15, wherein the cooling component is given the shape of a capital “T” due to the arrangement of the first part and the second part of the cooling component, the first part of the cooling component being arranged in a hole in the PBA.
